(19) United States
(12) Patent Application Publication
(10) Pub. No.: US 2008/0283944 A1
(43) Pub. Date: Nov. 20, 2008

(54) PHOTOSTRUCTURABLE GLASS MICROELECTROMECHANICAL (MEMs) DEVICES AND METHODS OF MANUFACTURE

(76) Inventor: Frank S. Geefay, Cupertino, CA (US)

Correspondence Address: Kathy Manke;Avago Technologies Limited, 4380 Ziegler Road, Fort Collins, CO, 80525, US

(21) Appl. No.: 11/750,606

(22) Filed: May 18, 2007

(51) Int. Cl. H01L 29/84; H01L 21/324

(52) U.S. Cl. 257/416; 438/53; 257/E29.324; 257/E21.211

(57) ABSTRACT

A Film Bulk Acoustic (FBA) MEMS device in a wafer level package including a photostructurable glass material and methods of manufacture are described.

### BACKGROUND

Microelectromechanical (MEMs) devices are experiencing greater interest to provide a variety of functions in a variety of applications. For example, many wireless devices rely on film bulk acoustic resonators (FBARs) to realize a variety of circuits. Illustratively, FBARs are used in filter circuits, transformers and microphones.

One type of FBAR includes a piezoelectric material disposed between two electrodes and disposed over a cavity in a substrate. The FBAR is enclosed by a cap structure, which is often referred to as a microcap structure. Vias are provided in the substrate, or the microcap, or both to provide electrical connections to the FBAR.

In many known FBAR structures the microcap and the substrate are made from a semiconductor such as silicon by etching features in the semiconductor. One etching technique useful in MEMS fabrication is known as deep reactive ion etching (DRIE). Among other benefits, DRIE provides high-aspect ratio features. While etching semiconductor materials is a comparatively mature technology, there are drawbacks to certain known methods, especially in MEMs applications. For instance, fabricating comparatively high aspect ratio features and comparatively deep features in material such as silicon often requires costly and time-consuming processes. In addition to requiring specialty tools to etch features, the DRIE and other reactive ion etching methods are generally not amenable to large scale or batch processing. Moreover, semiconductor materials such as silicon may interact with passive MEMS devices.

What is needed, therefore, are MEMs devices and methods of MEMs devices that overcomes at least the shortcomings described.

### SUMMARY

In accordance with an illustrative embodiment, a method of fabricating a microelectromechanical (MEM) device includes: selectively exposing at least a portion of a photostructurable glass substrate to radiation; heating the substrate to at least partially crystallize at least a portion of the exposed portion of the substrate; selectively etching at least a portion of the substrate in a solution to provide features in the substrate. The etching of the at least partially crystallized portions of the substrate proceeds at a significantly greater rate than the unexposed portions of the substrate.

In accordance with another illustrative embodiment, a film bulk acoustic structure (FBA) includes a photostructurable glass substrate; a cavity provided in a surface of the substrate; and an FBA disposed at least partially over the cavity.

In accordance with yet another illustrative embodiment, a microcap structure includes a photostructurable glass substrate; cavity provided in a surface of the substrate; and a glass gasket extending from the substrate.

### BRIEF DESCRIPTION OF THE DRAWINGS

Representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional view of an FBA structure in accordance with representative embodiment.

FIGS. 2A-2C are cross-sectional views of a fabrication sequence of an FBA device in accordance with a representative embodiment.

FIGS. 3A-3C are cross-sectional views of a fabrication sequence of a microcap structure in accordance with a representative embodiment.

FIGS. 4A-4D are cross-sectional views of a fabrication sequence of an FBA device having a microcap structure in accordance with a representative embodiment.

FIG. 5 is a cross-sectional view of an FBA structure in accordance with a representative embodiment.

### DEFINED TERMINOLOGY

The terms ‘a’ or ‘an’, as used herein are defined as one or more than one.

The term ‘plurality’ as used herein is defined as two or more than two.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of apparati, devices, materials and methods known to one of ordinary skill in the art may be omitted so as to not obscure the description of the example embodiments. Such apparati, devices, methods and materials are clearly within the scope of the present teachings. Furthermore, although described respect to a FBA device, the present teachings may be applied to other devices and structures. Generally, the present teachings may be applied to a variety of MEMs and packaging technologies.

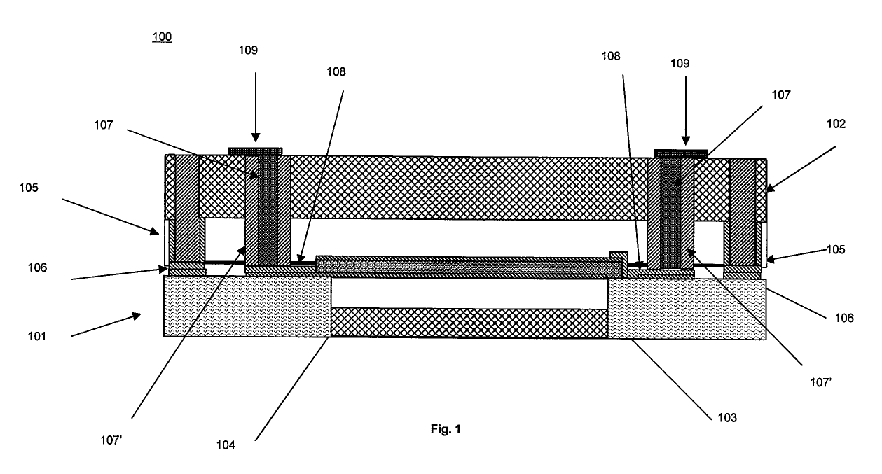

FIG. 1 is a cross-sectional view of an FBA structure 100 in accordance with a representative embodiment. The structure 100 includes a substrate 101 and a microcap 102 disposed thereover. As described more fully herein, the substrate 101 and the microcap 102 comprise a photostructurable glass having photostructured glass features formed therein. An FBA device 103 is disposed over a cavity 104, which is a feature formed in the substrate 101. The FBA device 103 is illustratively a resonator (FBAR) or a transducer structure including a piezoelectric element disposed between two electrodes.

The microcap 102 is usefully bonded to the substrate 101 via an adhesive layer 105 formed over a gasket as shown. The layer 105 is illustratively a metal such as gold and bonds to pads 106 formed over the substrate 101 and made of similar or identical material as the layer 105. Upon bonding of the microcap 102 to the substrate 101, the FBA device 103 is substantially packaged between the substrate 101 and the microcap 102. In certain embodiments, this bonding sequence provides hermetic packaging of the FBA device 103.

In representative embodiments, vias are usefully formed in microcap 102, or the substrate 101, or both. For example, vias 107 are formed by etching features in the microcap 102 and providing a conductive material therein. Notably, the vias 107 include an unexposed portion of photostucturable glass 107′, which allows for the selective etching of the vias 107 by methods described herein. The vias 107 provide an electrical connection between contacts 108 of the device 103 disposed over the substrate 101 and contacts 109 disposed over the microcap 102. As will be appreciated, contacts 108, 109 may be signal contacts for providing electrical signals to and retrieving electrical signals from the device 103.

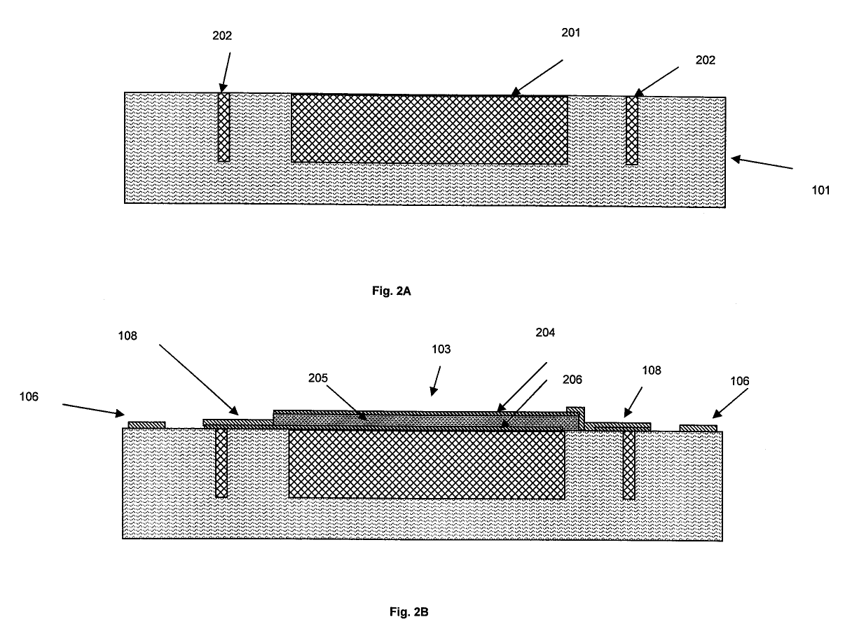

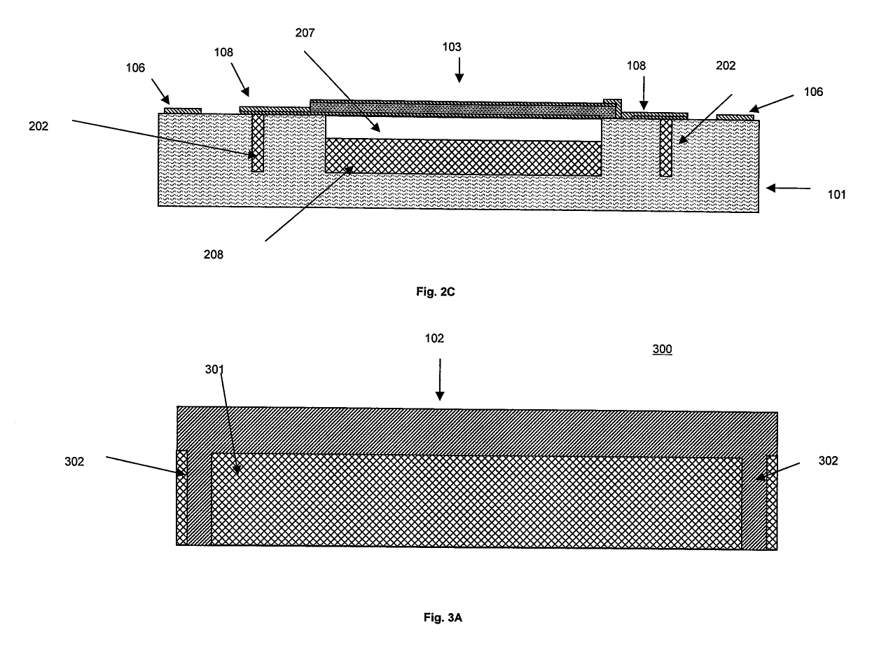

FIGS. 2A-2C are cross-sectional views of a method of fabricating an FBA device in accordance with a representative embodiment. FIG. 2A shows the substrate 101 having regions 102, 202 exposed to radiation and heated to increase their etch rates compared to the unexposed/remainder of the substrate. As noted, the substrate 101 comprises a photostructurable glass material. As used herein, the term photostructurable glass means a class of glass materials, which when properly exposed to ultraviolet (UV) radiation/light of a sufficient intensity and heat treated, becomes highly soluble in dilute (e.g., 10:1) hydrofluoric acid (HF) and mildly agitated with an megasonic agitator compared to the regions that are not exposed. Illustratively, the exposed and heated glass etches approximately 20 times to approximately 30 times more quickly than the adjacent unexposed areas. Thus comparatively deep, well defined etched features can be realized by placing a batch of wafers in dilute HF. As such, photostructured glass features are formed in a comparatively simple manner.

In representative embodiments, the photostructurable glass may be glass material having the tradename Foturan or Foturan Glass-Ceramic manufactured by Schott AG, Germany, and distributed by Invenios/Mikroglas Chemtech, GmbH, Germany; or glass material having the tradename Fotoform-Fotoceram manufactured by Corning Incorporated, Corning, N.Y. Notably, these glass materials have slightly different physical properties, but have significant common properties. As such, the selection of one over the other is user specific. The photostructurable glasses useful in the representative structures and methods have the property that when exposed by the proper intensity and wavelength of UV radiation silver atoms disassociate from the glass compound.

In an illustrative embodiment, the regions 102, 202 are formed by exposing the substrate 101 under mask to light in the range of approximately 290 nm to approximately 330 nm and having a suitable intensity to expose the photostructurable glass. The substrate 101 is then subject to a heat treatment of approximately 600° C., which causes the glass to crystallize around the silver atoms (cerimization). These crystallized areas etch at a rate of more than approximately 20 times greater than the etching rate in the unexposed vitreous regions thereabout. For example, the exposed/heat treated regions 102, 202 typically having an etch rate of about 25 μm per minute in 10:1 HF.

As will be readily appreciated by one of ordinary skill in the art, the disparity in the etch rates between the exposed and unexposed regions of the substrate 101 allows complex features to be exposed and etched into the exposed regions and etched. The combined advantages of the glass' insulating properties and ease of selective etching fundamentally provide other advantages as well. For example, a glass wafer which has been photostructured is less expensive than a similar silicon wafer with etched vias. The coefficient of thermal expansion can also be somewhat tailored by the vendor by comparatively minor variations in its chemical composition. In addition, the glass substrate 101 can be further heat treated at approximately 800° C. to form a higher temperature ceramic material which can be heated up to 700° C. if high temperature applications is required. Furthermore, the photostructurable glass material has a much lower dielectric constant (∈ᵣ=6.5) than silicon (∈ᵣ=12) resulting in lower electric loss.

FIG. 2B shows the FBA device 103 disposed over the substrate 101 and particularly, at least partially over the region 102. The device 103 includes an upper electrode 204, a piezoelectric element 205 and a lower electrode 206. Contacts 108 connect to the lower electrode 206 and the upper electrode 204 as shown. During the fabrication sequence, the pads 106 are formed.

The piezoelectric element 205 may be AlN, ZnO, lead zirconium titanate (PZT) or combinations thereof; the electrodes 204, 206 may be metal such as Mo, Pt, or W. Moreover, and as will be appreciated by one of ordinary skill in the art, mass loading layers of dielectric, ceramic and piezoelectric materials, and metals may be included. It is emphasized that the noted materials are merely illustrative.

The fabrication of the device 103 and the metallization (contacts, bond pads, etc.) are effected by known methods. For example, the methods of fabricating the device 103 and materials therefore may be as described, for example, in U.S. Pat. No. 6,384,697 entitled “Cavity Spanning Bottom Electrode of Substrate Mounted Bulk Wave Acoustic Resonator” to Ruby, et al. and assigned to the present assignee. The disclosure of this patent is specifically incorporated herein by reference. The metallization may be fabricated by one or more methods known to one of ordinary skill in the art, such as standard lift-off methods.

While the FBA device 103 may be fabricated directly on the substrate 101, alternatively the device 103 may be fabricated on another substrate and transferred to the substrate 101 by known methods. Notably, the thermal constraints on certain types of photostructurable glass materials may prohibit or curtail the use of known methods of the piezoelectric element 204. Therefore, it may be useful, depending on the photostructurable glass material selected, to transfer the FBA device 103 after fabrication on a substrate more tolerant of temperatures of fabrication.

FIG. 2C shows the FBA device 103 disposed over the substrate 101 after the etching of region 201 to form a cavity 207 beneath the device 103. Notably, the etching of the region 201 does not necessarily completely remove the exposed/heated treated region 201, and a portion 208 remains as shown. For example, by way of illustration, the depth of the cavity 207 may be approximately 5.0 μm or more. As noted, the etching is by a dilute HF solution and may be effected through an opening (not shown) through the layers of the device 103. The etching of the cavity and release of the etchant and etch material may be carried out by known methods, such as described in the referenced patent to Ruby, et al.

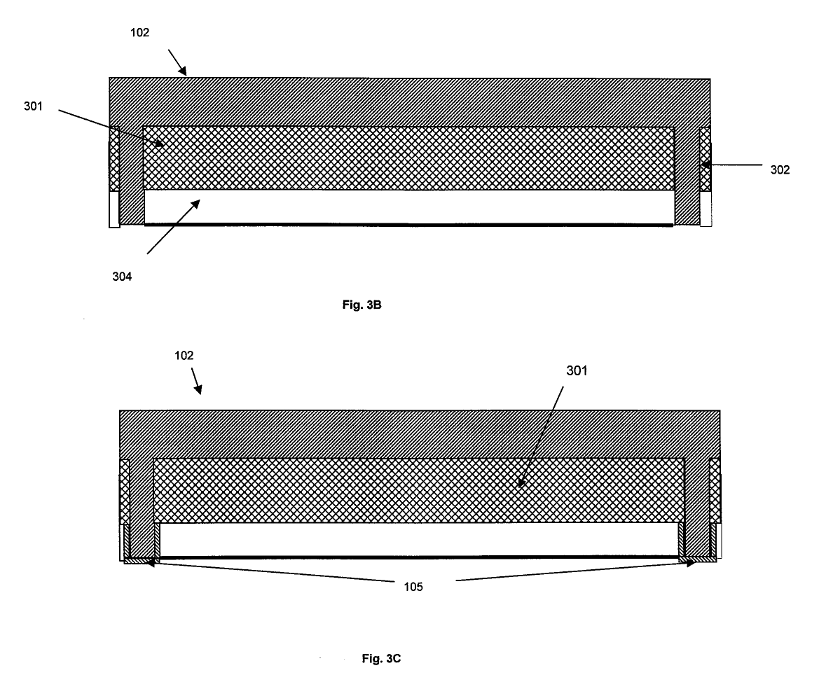

FIGS. 3A-3C are cross sectional views of a fabrication sequence of a microcap structure 300 in accordance with a representative embodiment. Many aspects of the method and many of the materials useful in fabricating the microcap structure 300 are common to those described in connection with the embodiments of FIGS. 1-2C. These details are generally omitted to avoid obscuring the description of the present embodiments.

FIG. 3A shows the microcap structure 300 in accordance with a representative embodiment. The microcap structure includes a region 301, which remains after exposure, heat treatment and etching. The structure 300 includes the microcap 102 and gasket 302, which remain after etching of the exposed region 301 as described herein. The microcap structure 300 is patterned with a gasket mask that surrounds the outer perimeter of the microcap structure and is approximately 15 μm to approximately 30 μm wide. The exposure depth of the region 301 is approximately 200 μm using diffused laser at the proper wave length. Illustratively, the exposure is effected using a blanket exposure using the gasket mask.

FIG. 3B shows the structure 300 after etching in dilute HF to define the gasket 302. The depth of etch is beneficially greater than the tallest feature disposed on substrate 101; typically approximately 8 μm to approximately 10 μm in depth.

FIG. 3C shows the microcap 102 substantially completed and including adhesive material 105 disposed at least partially over the gasket 302. The material 105 may be formed by depositing an adhesion metal followed by a metal such as gold. The gold is then patterned on the gasket 302. This adhesive may also be a polymer material such as BCB or Polyimide. Alternatively, the adhesive material 105 may be one of many solders known to one of ordinary skill in the art (e.g., a gold-tin alloy).

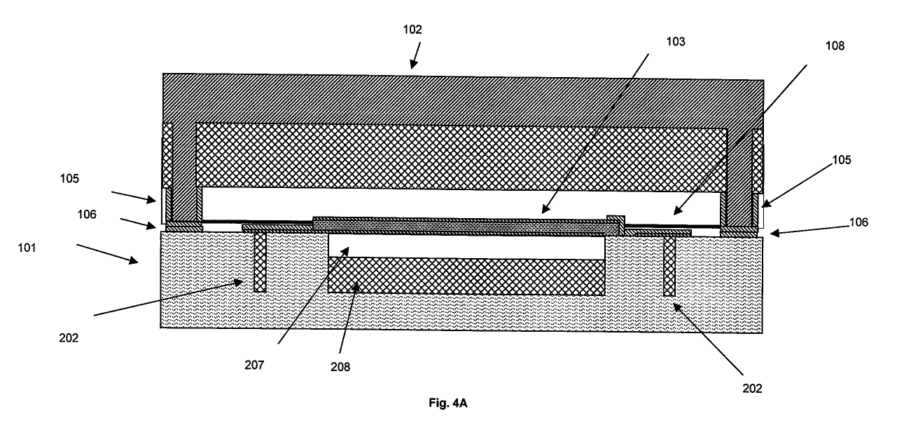

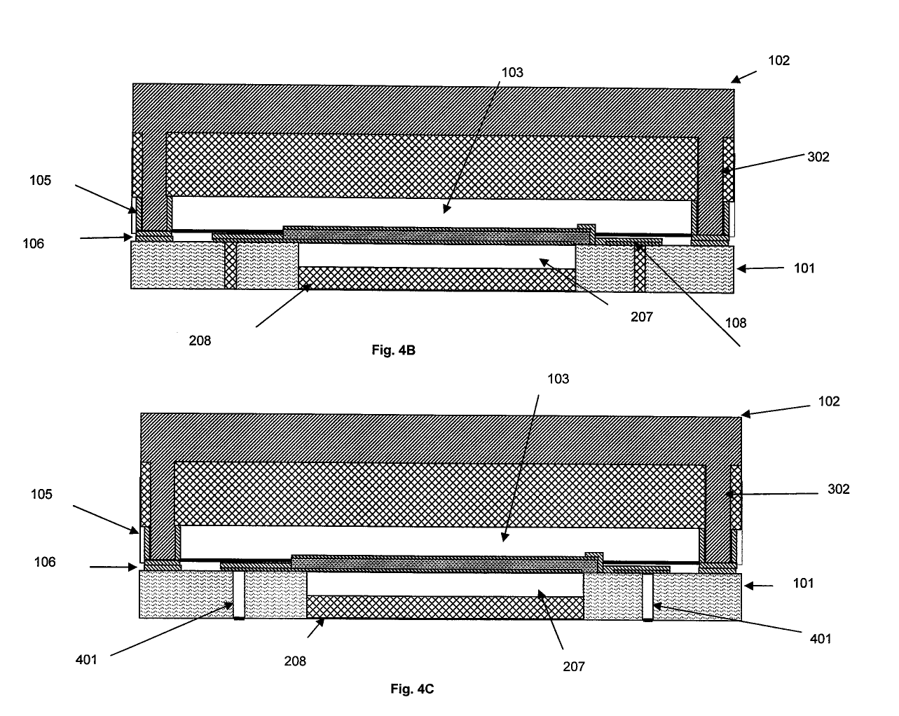

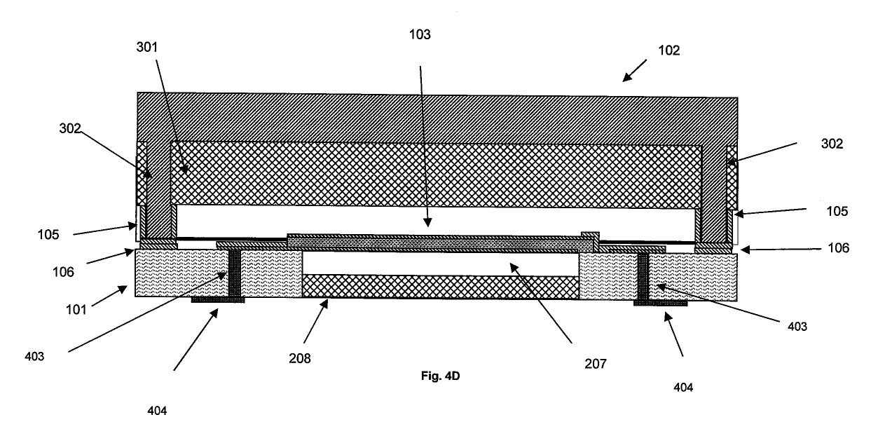

FIGS. 4A-4D are cross-sectional views of a fabrication sequence of an FBA device having a microcap structure in accordance with a representative embodiment.

FIG. 4A shows the microcap 102 bonded to the substrate 101 with the FBA device 103 disposed thereon. The bonding is effected by aligning and then bonding of the adhesive material 105 of the gasket and the bond gasket ring 106. In a representative embodiment, the bonding is either effected by a known technique such as by cold welding, Polymer bonding, solder bonding, or other known wafer bonding methods.

FIG. 4B shows the structure after reducing the thickness of the substrate 101 by a known method, such as wafer grinding. After the coarse removal of a desired later thickness, a fine polish (e.g., chemical mechanical polishing (CMP)) may be carried out. Among other reasons, the thinning of the substrate is used to reduce losses (improve Q-factor) and to reduce the thermal resistance as well to reveal regions 202 in the substrate 101.

FIG. 4C shows the structure after removal of the exposed and heat treated regions 202 using a dilute HF solution. Notably, prior to the etching, a mask (not shown) is provided over the backside (i.e., the substrate 101) to protect any exposed portions of the etchable glass under the cavity 208. The removal of the etchant and etched material in regions 202 provides vias 401 in the substrate 101 that may have comparatively high aspect ratios. In representative embodiments, the vias 401 have a width of approximately 20 μm to approximately 50 μm; and a depth of approximately 75 μm to approximately 150 μm.

FIG. 4D shows the structure after the vias 401 are plated to form conductive vias 403; and after contact pads 404 are formed over the lower surface of the substrate 101. In this sequence, other metallization may be completed to include for example contact pads, posts and solder bumps. These features may be formed by known methods, such as by plating or lift-off methods known in the art. As will be appreciated, the vias 402 are provided in the substrate 101 rather than in the microcap 102 as shown in FIG. 1. In addition, by similar fabrication sequences and variations thereof, the conductive vias, pads and conductive traces may be provided in both the substrate 101 and microcap 102.

FIG. 4D also shows the structure after grinding of the upper portion of the microcap structure 300. In a representative embodiment, the unexposed portion of the structure 300 may be removed by a known grinding method down to the vicinity of the exposed/heat treated region 301. As such, the microcap 102 that remains includes the region 301 and the gasket 302 as shown.

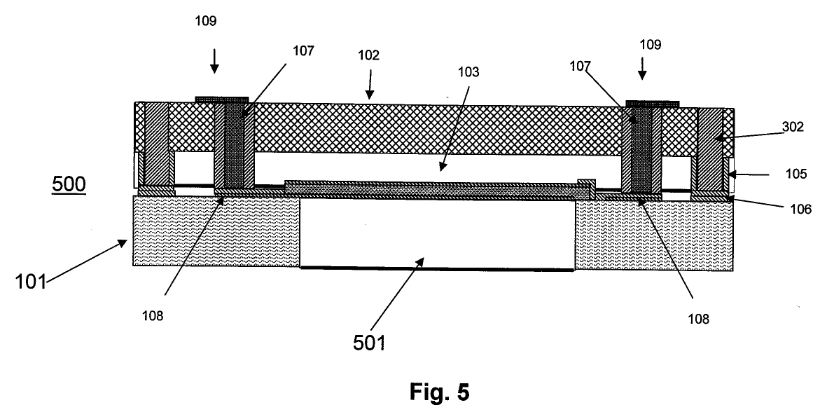

FIG. 5 is a cross-sectional view of an FBA structure 500 in accordance with a representative embodiment. Many aspects of the method and many of the materials useful in fabricating the structure 500 are common to those described in connection with the embodiments of FIGS. 1-4D. These details are generally omitted to avoid obscuring the description of the present embodiments.

In the representative embodiment, the FBA structure 500 includes a cavity 501 through the substrate 101. Such a structure may be useful in devices such as microphones of the type described in U.S. patent application Ser. Nos. 11/588,752, entitled “Piezoelectric Microphones”, filed Oct. 27, 2006; 11/604,478, entitled “Transducers with Annular Contacts” filed on Nov. 26, 2007; and 11/727,735, entitled Multi-Layer Transducers with Annular Contacts, filed on Apr. 19, 2007 all to R. Shane Fazzio, et al. The inventions disclosed in these applications are assigned to the present assignee and are specifically incorporated herein by reference.

In the present embodiment, the exposed/heat treated region 208 is removed to reveal the cavity 501. This may be carried out by foregoing the mask used in revealing the vias 401 as described previously. Otherwise, the fabrication sequence of the FBA structure 500 and features thereof is substantially identical to one or more of the sequences described in connection with the embodiments of FIGS. 1-4D.

In the representative embodiments described to this point, the exposure of the glass material to UV radiation is generally a blanket exposure, which provides suitable intensity to a depth of approximately 200 μm, to expose the glass so that cerimitization can be achieved as described. In other embodiments, more than one source of radiation for exposure regions with particularity is contemplated. For example, in one representative embodiment two or more UV radiation sources (e.g., UV lasers), each of requisite wavelength but not of sufficient intensity to expose the glass, are incident on a region of the glass so that their beams overlap in the region. If the combined intensity is greater than that required to expose the glass, then the glass will be selectively exposed. This allows one to select with significant precision a region of the glass to be exposed as only the overlapping regions, while not exposing all regions in the path of the individual beams. As will be appreciated, this allows for comparatively precise 3D features to be formed and, as applicable, the exposure of regions of the glass without the need for a mask.

In connection with illustrative embodiments, MEMs devices and methods of manufacture are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A method of fabricating a microelectromechanical (MEM) device, the method comprising:
selectively exposing at least a portion of a photostructurable glass substrate to radiation;
heating the substrate to at least partially crystallize the exposed portion of the substrate;
selectively etching at least a portion of the substrate in a solution to provide features in the substrate, wherein the etching of the at least partially crystallized portions of the substrate proceeds at a significantly greater rate than the unexposed portions of the substrate.

2. A method as claimed in claim 1, wherein the features comprise a cavity in a side of the substrate, and the method further comprises:
providing a film bulk acoustic resonator (FBAR) device over the cavity.

3. A method as claimed in claim 1, wherein the features include a via extending into the substrate and the method further comprises:
providing a conductor in the via.

4. A method as claimed in claim 1, wherein the method further comprises:
forming a microcap in another substrate, wherein the microcap structure has a gasket;
providing an adhesive material over the gasket; and
adhering the gasket to the substrate.

5. A method as claimed in claim 4, wherein the features include a via extending into the other substrate and the method further comprises:
providing a conductor in the via.

6. A method as claimed in claim 1, wherein the exposing further comprises:
directing light from a first light source to a region of the substrate;
directing light from a second light source to the region of the substrate, wherein the light from the first and second light sources overlap at least partially in the region.

7. A method as claimed in claim 1, wherein the exposing substantially separates silver atoms from a glass compound comprising the substrate, and the heating substantially crystallizes the glass around the silver atoms.

8. A film bulk acoustic structure (FBA), comprising:
a photostructurable glass substrate;
a cavity provided in a surface of the substrate; and
an FBA disposed at least partially over the cavity.

9. An FBA structure as claimed in claim 8, further comprising at least one conductive via disposed in the substrate and adapted to connect a contact pad on another surface of the substrate to a contact pad on the surface.

10. An FBA structure as claimed in claim 8, further comprising a microcap structure disposed over the substrate and including a gasket, which contact the surface.

11. An FBA structure as claimed in claim 10, further comprising at least one conductive via disposed in the microcap and adapted to connect a contact pad on the microcap to a contact pad on the surface.

12. An FBA structure as claimed in claim 8, wherein the cavity extends through the substrate from the surface through another surface.

13. An FBA structure as claimed in claim 12, wherein the FBA is a microphone.

14. An FBA structure as claimed in claim 8, wherein the FBA is a resonator (FBAR).

15. A microcap structure, comprising:
a photostructurable glass substrate;
a cavity provided in a surface of the substrate; and
a glass gasket extending from the substrate.

16. A microcap structure as claimed in claim 15, further comprising an adhesive layer disposed at least partially over the gasket, and adapted to bond the microcap structure to another structure.

17. A microcap structure as claimed in claim 16, wherein the other substrate is a semiconductor substrate.

18. A microcap structure as claimed in claim 15, further comprising at least one conductive via disposed in the microcap and adapted to connect a contact pad on the microcap to another contact pad.

19. A microcap structure as claimed in claim 15, wherein the glass gasket is a photostructurable glass.

20. A microcap structure as claimed in claim 16, wherein the other substrate further comprises at least one conductive via.
